(19) United States
(12) Patent Application Publication
(10) Pub. No.: US 2026/0282258 A1
(43) Pub. Date: Sep. 17, 2026

(54) EXPANSION CARD SLOT, MAIN BOARD, AND ELECTRONIC DEVICE

(71) Applicant: ASUS GLOBAL PTE. LTD., Singapore (SG)

(72) Inventors: Fang-Ping YUAN, Singapore (SG); Chao XU, Singapore (SG); Chuan-Guang QU, Singapore (SG)

(73) Assignee: ASUS GLOBAL PTE. LTD., Singapore (SG)

(21) Appl. No.: 19/291,956

(22) Filed: Aug. 6, 2025

(30) Foreign Application Priority Data
Mar. 12, 2025 (CN) 202510297941.4

(51) Int. Cl. H05K 5/02

(52) U.S. Cl. CPC H05K 5/026

(57) ABSTRACT

The disclosure provides an expansion card slot, a main board, and an electronic device. The expansion card slot is suitable for being mounted on a main board. An expansion bus specification supported by the expansion card slot defines a plurality of adjacent power supply output contacts, and the expansion card slot further includes a power supply pin, where the power supply pin simultaneously corresponds to the plurality of power supply output contacts. The disclosure further provides a main board having the expansion card slot and an electronic device.

### CROSS-REFERENCE TO RELATED APPLICATION

This application claims the priority benefit of Chinese application serial No. 202510297941.4, filed on March 12, 2025. The entirety of the above-mentioned patent application is hereby incorporated by reference herein and made a part of the specification.

### BACKGROUND OF THE INVENTION

### Field of the Invention

The disclosure relates to the field of main board technologies, and in particular, to an expansion card slot, a main board having the expansion card slot, and an electronic device having the main board.

### Description of the Related Art

Restricted by a pin size of an expansion card slot, power that can be transmitted by the expansion card slot is limited. For example, for a peripheral component interconnect express (PCI-E) specification, a wattage of power that can be transmitted by a connector is 75 W. The wattage of the transmitted power cannot meet a requirement of a current PCI-E display card.

Therefore, how to increase the wattage of power that can be transmitted by a slot under an existing expansion card slot architecture becomes an urgent problem to be resolved in the art.

### BRIEF SUMMARY OF THE INVENTION

An objective of the disclosure is to provide an expansion card slot, a main board, and an electronic device, to resolve at least one of the foregoing problems.

The disclosure provides an expansion card slot, suitable for being mounted on a main board. An expansion bus specification supported by the expansion card slot defines a plurality of adjacent power supply output contacts, and the expansion card slot further includes a power supply pin, where the power supply pin simultaneously corresponds to the plurality of power supply output contacts.

The disclosure further provides a main board. The main board includes a board body and an expansion card slot. The expansion card slot is arranged on the board body, suitable for mounting an expansion card. An expansion bus specification supported by the expansion card slot defines a plurality of adjacent power supply output contacts, and the expansion card slot further includes a power supply pin, where the power supply pin simultaneously corresponds to the plurality of power supply output contacts.

The disclosure further provides an electronic device, including an expansion card and a main board. The main board includes a board body and an expansion card slot. The expansion card slot is arranged on the board body, suitable for mounting an expansion card. An expansion bus specification supported by the expansion card slot defines a plurality of adjacent power supply output contacts, and the expansion card slot further includes a power supply pin, where the power supply pin simultaneously corresponds to the plurality of power supply output contacts.

In the disclosure, the expansion card slot includes the power supply pin. The width of the power supply pin simultaneously corresponds to the plurality of power supply output contacts, increasing the wattage of power that can be transmitted by the expansion card slot, to meet a power requirement of a current expansion card (especially a display card).

### BRIEF DESCRIPTION OF THE DRAWINGS

FIG. 1 is a schematic diagram of a main board according to an embodiment of the disclosure;

FIG. 2 is a schematic diagram of an expansion card slot according to an embodiment of the disclosure;

FIG. 3 illustrates a pin definition of a peripheral component interconnect express specification;

FIG. 4 is a schematic diagram of a power supply pin according to an embodiment of the disclosure;

FIG. 5 is a schematic diagram of a power supply pin according to another embodiment of the disclosure;

FIG. 6 is a schematic partial diagram of an expansion card suitable for being mounted in an expansion card slot of the disclosure according to an embodiment of the disclosure;

FIG. 7 is a schematic block diagram of an electronic device according to an embodiment of the disclosure;

FIG. 8 is a schematic block diagram of an electronic device according to another embodiment of the disclosure; and

FIG. 9 is a schematic block diagram of an electronic device according to another embodiment of the disclosure.

### DETAILED DESCRIPTION OF THE EMBODIMENTS

More detailed descriptions of specific embodiments of the disclosure are provided below with reference to the schematic diagrams. The features and advantages of the disclosure are described more clearly according to the following descriptions and claims. It should be noted that the drawings are all in a very simplified form and are not drawn to accurate scale, but are merely used for convenience and clarity of descriptions of the embodiments of the disclosure.

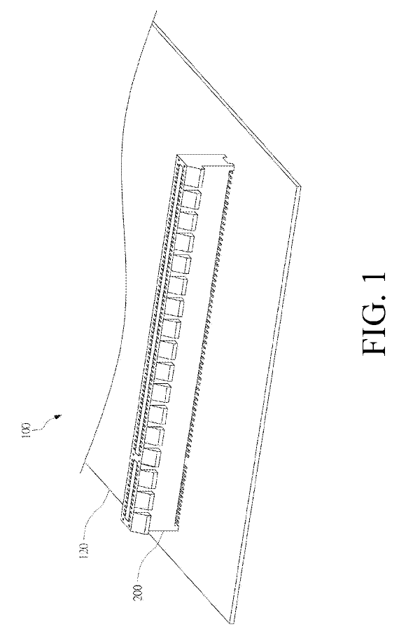

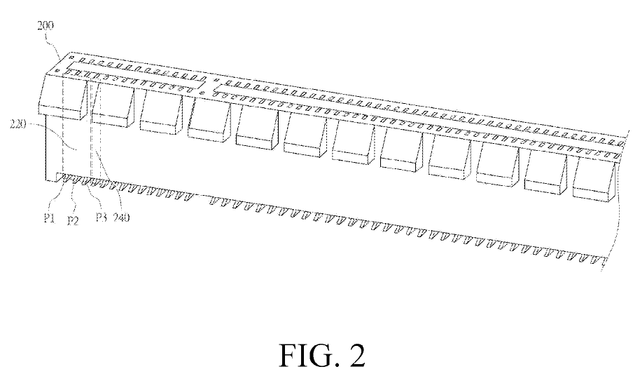

FIG. 1 is a schematic diagram of a main board 100 according to an embodiment of the disclosure. FIG. 2 is a schematic diagram of an expansion card slot 200 according to an embodiment of the disclosure.

As shown in the figure, the main board 100 includes a board body 120 and an expansion card slot 200. The expansion card slot 200 is arranged on the board body 120, and the expansion card slot is suitable for mounting an expansion card (not shown in the figure).

The expansion card slot 200 supports an expansion bus specification. The expansion bus specification defines a plurality of adjacent power supply output contacts P1, P2, and P3, and the power output contacts P1, P2, and P3 are equipotential contacts. In an embodiment, the expansion card slot 200 supports a peripheral component interconnect express (PCI-E) specification. In an embodiment, the expansion card slot 200 is suitable for mounting a display card which supports the peripheral component interconnect express specification.

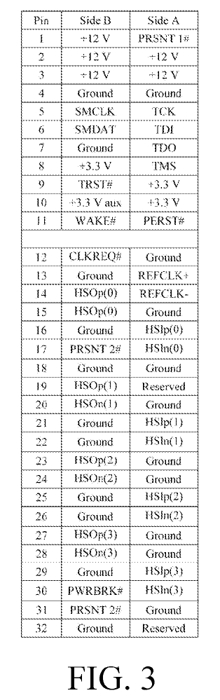

Referring to FIG. 3, FIG. 3 illustrates a pin definition of a peripheral component interconnect express specification. As shown in the figure, in terms of the peripheral component interconnect express specification, in an embodiment, contacts numbered 2 and 3 on a side A, and contacts numbered 1, 2, and 3 on a side B are all +12 V contacts, which are understood as adjacent power supply output contacts P1, P2, and P3 in the disclosure. In addition, in an embodiment, contacts numbered 9 and 10 on the side A are both 3.3 V contacts, which are also understood as adjacent power supply output contacts P1, P2, and P3 in the disclosure.

Referring back to FIG. 2, the expansion card slot 200 in the disclosure includes a power supply pin 220 and a plurality of signal transmission pins 240. A width of the power supply pin 220 is greater than a width of the signal transmission pin 240, and the power supply pin is suitable for simultaneously corresponding to the plurality of adjacent power supply output contacts P1, P2, and P3.

In addition, in an embodiment, a thickness of the power supply pin 220 of the disclosure is greater than a thickness of the signal transmission pin 240, thereby further increasing a sectional dimension of a power supply pin 440.

In addition, in an embodiment, the power supply pin 220 and the signal transmission pins 240 are made of different materials. In an embodiment, the power supply pin 220 is made of a metal material having a relatively high electrical conductivity, to reduce impedance of the power supply pin 220 and increase a current that can be transmitted (or a wattage of power that can be supported) by the expansion card slot 200.

For a specific structure of the power supply pin 220 in the disclosure, reference is made to described content of the following paragraphs.

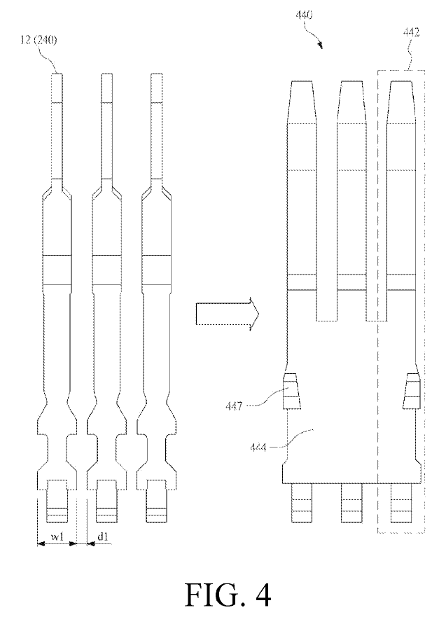

Referring to FIG. 4, FIG. 4 is a schematic diagram of a power supply pin 440 according to an embodiment of the disclosure. In the figure, the left half shows a power supply pin 12 of a conventional expansion card slot, and the right half shows the power supply pin 440 of this embodiment. The power supply pin 12 is directly used as the signal transmission pin 240 of the disclosure.

As shown in the figure, the power supply pin 440 includes a plurality of pin portions 442 and a connection portion 444. The plurality of pin portions 442 respectively corresponds to the plurality of power supply output contacts P1, P2, and P3, and the connection portion 444 connects the plurality of pin portions 442. The power supply pin 440 is designed to match the existing main board 100 without changing an electrical contact location that is on the main board 100 and configured to mount the expansion card slot 200.

As shown in the figure, a size and a position of each pin portion 442 of the power supply pin 440 in this embodiment correspond to those of the power supply pin 12 of the conventional expansion card slot, and a width of the connection portion 444 is significantly greater than a sum of widths of the plurality of pin portions 442. That is, a projection area of the connection portion 444 on the main board 100 is greater than a sum of projection areas of the plurality of power supply pins 12 on the main board 100. In this way, overall impedance of the power supply pin 440 of the disclosure is lower than impedance of the plurality of corresponding conventional power supply pins 12 connected in parallel, which is beneficial to increasing a current that can be transmitted (or a wattage of power that can be supported) by the expansion card slot 200.

In addition, a size and a position of each pin portion 442 correspond to those of the power supply pin 12 of the conventional expansion card slot. The power supply pin 440 is designed to match the existing main board 100 and an expansion card 300 without changing an electrical contact location that is on the main board 100 and configured to mount the expansion card slot 200, and without changing a gold finger design on the expansion card 300.

Further, to ensure structural stability of the power supply pin 440 in the expansion card slot, opposite sides of the power supply pin 440 are respectively provided with a fixing structure 447, to clamp and fix the power supply pin 440 in the expansion card slot. In an embodiment, the fixing structure 447 is a bump or a hook.

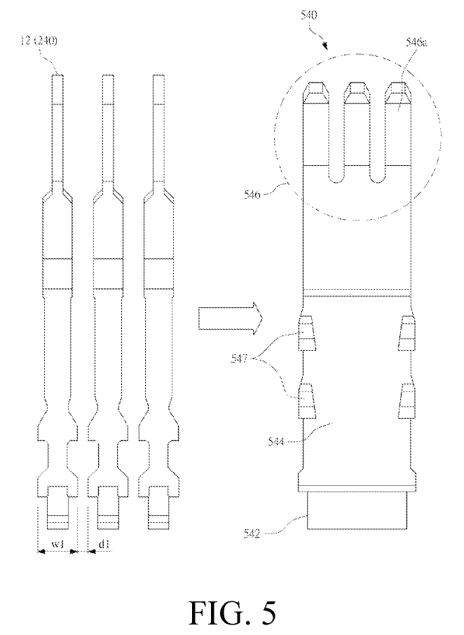

Referring to FIG. 5, FIG. 5 is a schematic diagram of a power supply pin 540 according to another embodiment of the disclosure. In the figure, the left part of the figure shows a power supply pin 12 of a conventional expansion card slot, and the right half shows the power supply pin 540 of this embodiment.

As shown in the figure, the power supply pin 540 includes an insertion portion 542, a middle section 544, and an abutting portion 546 connected in sequence. The insertion portion 542 is suitable for being inserted into the board body 120, and the abutting portion 546 is suitable for being electrically connected to an expansion card. The insertion portion 542 and the abutting portion 546 are connected to opposite sides of the middle section 544, and widths of the insertion portion 542, the middle section 544, and the abutting portion 546 are approximately the same.

The insertion portion 542 simultaneously corresponds to the plurality of power supply output contacts P1, P2, and P3. The abutting portion 546 simultaneously corresponds to the plurality of power supply output contacts P1, P2, and P3. The width of the insertion portion 542 is equivalent to a sum of widths w1 of the plurality of corresponding conventional power supply pins 12 and spacing distances d1 thereof. Therefore, overall impedance of the power supply pin 540 of the disclosure is lower than impedance of the plurality of corresponding conventional power supply pins 12 connected in parallel, which is beneficial to increasing a current that can be transmitted (or a wattage of power that can be supported) by the expansion card slot 200.

Secondly, as shown in the figure, in this embodiment, the abutting portion 546 of the power supply pin 540 is divided into a plurality of contact regions 546a corresponding to a gold finger configuration on the expansion card 300, to avoid a problem of nonuniform stress caused by an excessively large contact region, and further prevent the reliability of electrical contact between the abutting portion 546 and the expansion card 300 from being affected. However, the disclosure is not limited thereto. In another embodiment, the abutting portion 546 has only a single contact region, and abuts against a plurality of gold fingers of the expansion card 300.

In addition, compared with the embodiment in FIG. 4, only one fixing structure 447 is arranged on each side of the power supply pin 440 to be clamped to the expansion card slot. In this embodiment, a plurality of fixing structures 547 is respectively arranged on the two sides of the middle section 544 of the power supply pin 540, to increase structural stability of the power supply pin 540 in the expansion card slot.

In conclusion, different from the conventional expansion card slot 200, the power supply pin 440 or 540 provided in the disclosure includes a plurality of adjacent power supply output contacts P1, P2, and P3. Currents transmitted by the power supply output contacts P1, P2, and P3 having a same potential are transmitted through the same power supply pin 440 or 540.

Compared with a conventional expansion card slot using a plurality of power supply pins 12 to transmit currents of the power supply output contacts P1, P2, and P3 respectively, in the disclosure, a sectional dimension of the power supply pin 440 or 540 is significantly greater than a sum of sectional dimensions of the power supply pins 12, which is beneficial to increasing a current that can be transmitted (or a wattage of power that can be supported) by the expansion card slot 200, to meet a requirement of a high-performance expansion card.

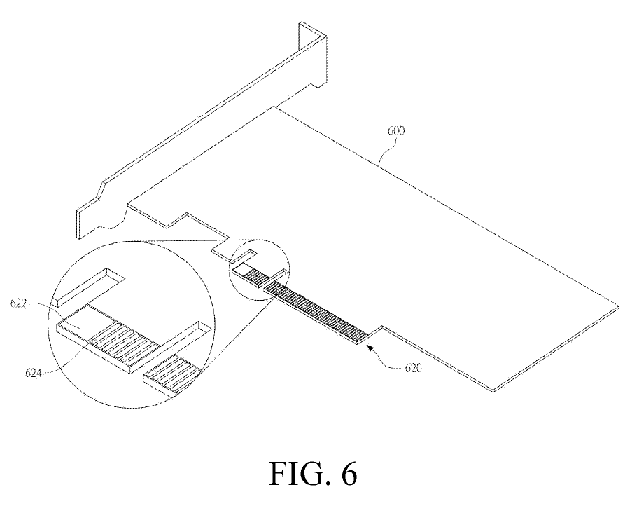

Referring to FIG. 6, FIG. 6 is a schematic partial diagram of an expansion card 600 suitable for being mounted in an expansion card slot 200 of the disclosure according to an embodiment of the disclosure.

As shown in the figure, the expansion card 600 includes an expansion card connector 620. The expansion card connector 620 is suitable for being inserted into the expansion card slot 200. An expansion bus specification supported by the expansion card 600 defines a plurality of adjacent power supply input contacts on the expansion card connector 620. The expansion card connector 620 further includes a power supply gold finger 622 and a plurality of signal transmission gold fingers 624. The power supply gold finger 622 simultaneously corresponds to a plurality of power supply input contacts. In an embodiment, as shown in the figure, a width of the power supply gold finger 622 is greater than a width of the signal transmission gold finger 624.

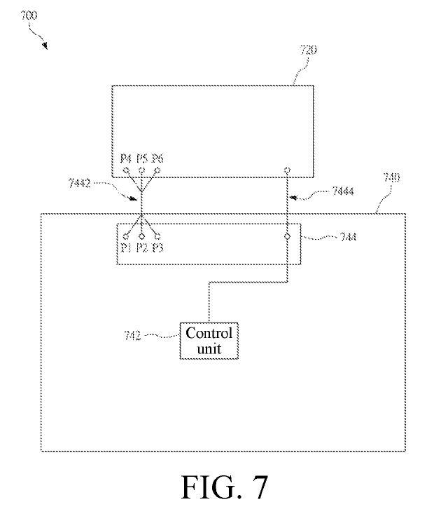

FIG. 7 is a schematic block diagram of an electronic device according to an embodiment of the disclosure.

As shown in the figure, the electronic device 700 includes an expansion card 720 and a main board 740. The main board 740 includes a control unit 742. The main board 740 is the main board 100 shown in FIG. 1.

The main board 740 has an expansion card slot 744. The expansion card slot 744 is suitable for mounting the expansion card 720. An expansion bus specification supported by the expansion card slot 744 defines a plurality of adjacent power supply output contacts P1, P2, and P3. The expansion card slot 744 further includes a power supply pin 7442, where the power supply pin 7442 simultaneously corresponds to the plurality of adjacent power supply output contacts P1, P2, and P3, and is suitable for transmitting power to a plurality of corresponding adjacent power supply input contacts P4, P5, and P6 on the expansion card 720.

In an embodiment, the expansion card slot 744 is the expansion card slot 200 shown in FIG. 1, and the expansion card 720 is the expansion card 600 shown in FIG. 6. However, the disclosure is not limited thereto. In another embodiment, the expansion card slot 744 is the expansion card slot 200 shown in FIG. 1, and the expansion card 720 is a conventional expansion card. Further, in another embodiment, the expansion card slot is a conventional expansion card slot, and the expansion card 720 is the expansion card 600 shown in FIG. 6.

The control unit 742 is suitable for determining a specification of the expansion card 720 by using the expansion card slot 744, to control an operating parameter of the expansion card 720 (such as, power consumption of the expansion card 720 or an operating frequency of a graphics processing unit on the expansion card 720).

In an embodiment, as shown in the figure, the control unit 742 communicates with the expansion card 720 by using a reserved pin 7444 of the expansion card slot 744, to obtain the data and control operation of the expansion card 720. However, the disclosure is not limited thereto.

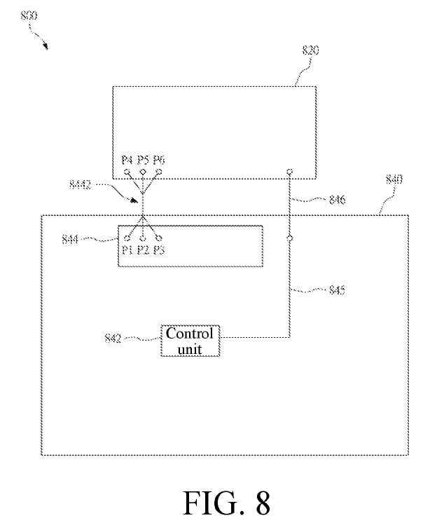

In another embodiment, referring to FIG. 8, FIG. 8 is a schematic block diagram of an electronic device 800 according to another embodiment of the disclosure.

As shown in the figure, the electronic device 800 includes an expansion card 820 and a main board 840. The main board 840 includes a control unit 842. The main board 740 is the main board 100 shown in FIG. 1.

The main board 840 has an expansion card slot 844. The expansion card slot 844 is suitable for mounting the expansion card 820. The expansion card slot 844 further includes a power supply pin 8442, where the power supply pin 8442 simultaneously corresponds to the plurality of adjacent power supply output contacts P1, P2, and P3. In an embodiment, the expansion card slot 744 is the expansion card slot 200 shown in FIG. 1.

Compared with the embodiment in FIG. 7, in this embodiment, the control unit 842 of the main board 840 communicates, by using a system control bus 845 on the main board 840 and by using another signal line 846, with the expansion card 820 inserted into the expansion card slot 844.

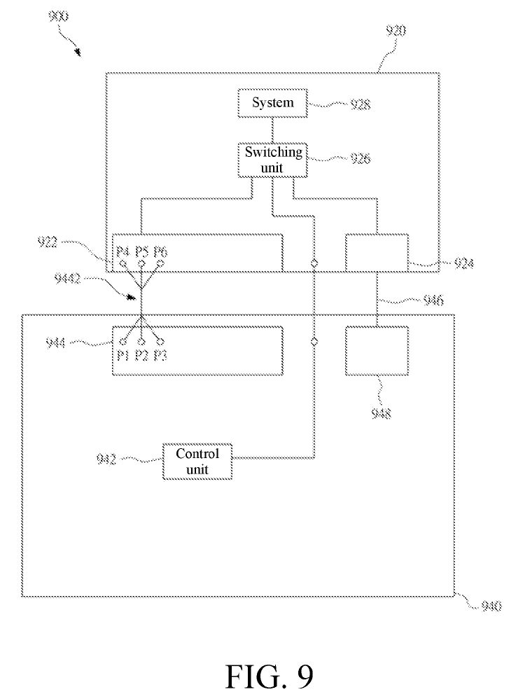

FIG. 9 is a schematic block diagram of an electronic device 900 according to another embodiment of the disclosure.

As shown in the figure, the electronic device 900 includes an expansion card 920 and a main board 940, where the main board 940 includes a control unit 942. The main board 940 is the main board 100 shown in FIG. 1.

In this embodiment, the expansion card 920 includes an expansion card connector 922, a power supply connector 924, and a switching element 926. The expansion card connector 620 and the power supply connector 924 are both configured to obtain power from the main board 920. The switching element 926 is electrically coupled to the expansion card connector 922 and the power supply connector 924, and the switching element is suitable for deciding a power source of the expansion card 920 and providing power to a system 928 on the expansion card 920. For a display card, the system 928 includes a graphics processing unit (GPU).

When the control unit 942 determines that rated power consumption of the expansion card 920 is less than or equal to a power supply wattage supported by the power supply pin 9442 of the expansion card slot 944, the control unit 942 notifies the switching element 926 to switch to the expansion card connector 922 to obtain power from the power supply pin 9442. On the contrary, when the control unit determines that the rated power consumption of the expansion card 920 is greater than the power supply wattage supported by the power supply pin 9442, the control unit 942 notifies the switching element 926 to switch to the power supply connector 924, to obtain power from the power supply connector 948 corresponding to the main board 940 by using a power transmission line 946.

In an embodiment, the switching element 926 is a power supply change-over switch, and the switching element is suitable for switching between the expansion card connector 922 and the power supply connector 924, to decide whether power is provided by the expansion card connector 922 or the power supply connector 924.

However, the disclosure is not limited thereto. In another embodiment, the expansion card connector 922 and the power supply connector 924 are power supplies of different phases, and the switching element 926 decides whether the expansion card connector 922 or the power supply connector 924 supplies power by switching the phase of the power supply.

In the disclosure, the expansion card slot 200, 744, 844, or 944 includes the power supply pin 220, 440, 540, 7442, 8442, or 9442. The width of the expansion card slot 200, 744, 844, or 944 simultaneously corresponds to the plurality of power supply output contacts P1, P2, P3, which is beneficial to increasing a wattage of power that can be transmitted by the expansion card slot 200, 744, 844, or 944, to meet a power requirement of a current expansion card (especially a display card).

Although the disclosure is described with reference to the above embodiments, the embodiments are not intended to limit the disclosure. A person skilled in the art makes variations and modifications without departing from the spirit and scope of the disclosure. Therefore, the protection scope of the disclosure is subject to the claims.

What is claimed is:

1. A main board, comprising:
a board body; and
an expansion card slot, arranged on the board body and suitable for mounting an expansion card, wherein an expansion bus specification supported by the expansion card slot defines a plurality of adjacent power supply output contacts, and the expansion card slot further comprises a power supply pin, wherein the power supply pin simultaneously corresponds to the plurality of power supply output contacts.

2. The main board according to claim 1, wherein the expansion bus specification is PCI-E.

3. The main board according to claim 1, wherein the plurality of power supply output contacts is suitable for outputting equipotential electrical energy.

4. The main board according to claim 1, wherein the expansion card supports the expansion bus specification and the expansion card comprises an expansion card connector, wherein the expansion bus specification defines a plurality of adjacent power supply input contacts on the expansion card connector, and the expansion card connector further comprises a power supply gold finger, wherein the power supply gold finger simultaneously corresponds to the plurality of power supply input contacts.

5. The main board according to claim 1, further comprising: a control unit, suitable for determining a specification of the expansion card by using the expansion card slot.

6. The main board according to claim 5, wherein the control unit communicates with the expansion card by using a system control bus.

7. The main board according to claim 5, wherein the control unit communicates with the expansion card by using a reserved pin of the expansion card slot.

8. The main board according to claim 5, wherein the expansion card comprises an expansion card connector and a power supply connector, wherein when the control unit determines that rated power consumption of the expansion card is less than a power supply wattage supported by the power supply pin, the control unit notifies the expansion card to obtain power from the power supply pin.

9. The main board according to claim 1, wherein the power supply pin comprises a plurality of pin portions and a connection portion, wherein the plurality of pin portions respectively corresponds to the plurality of power supply output contacts, and the connection portion connects the plurality of pin portions.

10. The main board according to claim 1, wherein the expansion card slot further comprises a plurality of signal transmission pins, wherein a width of the power supply pin is greater than a width of the signal transmission pin.

11. The main board according to claim 10, wherein a thickness of the power supply pin is greater than a thickness of the signal transmission pin.

12. The main board according to claim 10, wherein an electrical conductivity of a material of the power supply pin is higher than an electrical conductivity of a material of the signal transmission pin.

13. The main board according to claim 1, wherein the power supply pin comprises an insertion portion, a middle section, and an abutting portion connected in sequence, wherein the insertion portion is suitable for being inserted into the board body, and the abutting portion is suitable for being electrically connected to the expansion card.

14. The main board according to claim 13, wherein widths of the insertion portion, the middle section, and the abutting portion are the same.

15. An electronic device, comprising:
an expansion card; and
a main board, comprising:
a board body; and
an expansion card slot, arranged on the board body and suitable for mounting the expansion card, wherein an expansion bus specification supported by the expansion card slot defines a plurality of adjacent power supply output contacts, and the expansion card slot further comprises a power supply pin, wherein the power supply pin simultaneously corresponds to the plurality of power supply output contacts.

16. An expansion card slot, suitable for being arranged on a circuit board, wherein an expansion bus specification supported by the expansion card slot defines a plurality of adjacent power supply output contacts, and the expansion card slot comprises a power supply pin, wherein the power supply pin simultaneously corresponds to the plurality of power supply output contacts.
